(19) United States
(12) Patent Application Publication
(10) Pub. No.: US 2007/0176268 A1
(43) Pub. Date: Aug. 2, 2007

(54) Socketless planar semiconductor module

(75) Inventors: Jong-Joo Lee, Suwon-si (KR); Moon-Jung Kim, Suwon-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/646,541

(22) Filed: Dec. 28, 2006

(30) Foreign Application Priority Data
Jan. 27, 2006 (KR) 10-2006-0008987

(51) Int. Cl. H01L 23/495

(52) U.S. Cl. 257/666

(57) ABSTRACT

A semiconductor module may include a printed circuit board that may have a first surface, a second surface, and at least one fixture hole. A semiconductor device may be mounted on the first surface of the printed circuit board. At least one connection terminal may be provided on one of the first surface or the second surface of the printed circuit board that may connect with connection pads of a motherboard. The printed circuit board may be connected to the motherboard through the at least one fixture hole such the connection terminals may be aligned with the connection pad and one of the first surface and second surface of the printed circuit board may face a major surface of the motherboard.

### PRIORITY STATEMENT

This U.S. non-provisional application claims the benefit of priority under 35 U.S.C. §119 from Korean Patent Application No. 10-2006-0008987, filed on Jan. 27, 2006, in the Korean Intellectual Property Office (KIPO), the disclosure of which is incorporated herein in its entirety by reference.

### BACKGROUND

1. Field

Example, non-limiting embodiments relate generally to semiconductor devices, for example, a semiconductor memory module may include semiconductor devices mounted on a printed circuit board.

2. Description of the Related Art

A semiconductor module may include a plurality of semiconductor devices that may be mounted on a printed circuit board (PCB) for performing a given function. For example, the semiconductor module may be a dynamic random access memory (DRAM) module or a flash memory module. The semiconductor module may be regarded and treated as a single part. A standardized part bundle may be substituted for internal constituent parts of an electronic device, for example a personal computer, to simplify and contribute to the automation of assembly.

Electronic digital devices, for example, mobile telephones, personal digital assistants (PDAs), and personal computers, may be becoming slimmer and the size of an electronic device on which the semiconductor module may be mounted may be becoming smaller. Accordingly, there may be a need for a semiconductor module having a new structure suitable for slimmer digital devices.

A conventional semiconductor module, for example the semiconductor module disclosed in FIG. 2 of U.S. Pat. No. 6,542,393 entitled “Dual-bank Memory Module with Stacked DRAM Chips Having a Concave-shaped re-route PCB in-between,” may be mounted on a motherboard by vertically inserting it into a concave-shaped socket of motherboard. Metal contact pads may be provided on an end of a printed circuit board for the semiconductor module. The metal contact pads may be used as connection terminals when the semiconductor module is vertically inserted into the concave-shaped socket of the motherboard, and may complete an electrical connection.

There may be limitations in making a slim digital device in which a semiconductor module may be mounted because the semiconductor module is connected with the motherboard in a vertical direction. Thus, the structure of a conventional semiconductor module may not be suitable for slimmer digital devices. In addition, the use of an interconnect, for example a socket, for connecting between the semiconductor module and the motherboard may cause signal delay and a connection defect.

### SUMMARY

Example, non-limiting embodiments may provide a planar semiconductor module capable of completing an electrical connection with a motherboard within a smaller area and without using a socket to connect with the motherboard.

In an example, non-limiting embodiment, a socketless planar semiconductor module may include a printed circuit board having a first surface, a second surface, and at least one fixture hole. At least one first semiconductor device may be mounted on the first surface of the printed circuit board. A plurality of connection terminals may be provided on one of the first surface or the second surface of the printed circuit board that may connect with connection pads of a motherboard. The printed circuit board may be connected to the motherboard through the at least one fixture hole such the connection terminals may be aligned with the connection pad and one of the first surface and one of the first surface and the second surface of the printed circuit board may face a major surface of the motherboard.

According to an example, non-limiting embodiment, the at least one first semiconductor device may be mounted on the printed circuit board using leads or conductive bumps.

According to an example, non-limiting embodiment, the at least one first semiconductor device may include a plurality of semiconductor devices, the plurality of semiconductor devices may be mounted on the first surface of the printed circuit board and may be arranged in one row or in two rows.

According to an example, non-limiting embodiment, the at least one connection terminal may be a printed circuit pattern on an elastic member on the printed circuit board, a metal pin that may be on an elastic member on the printed circuit board, or a metal spring on the printed circuit board.

According to an example, non-limiting embodiment, the at least one connection terminal may be a plurality of connection terminals that may be arranged in a staggered layout, or in a plurality of rows.

According to an example, non-limiting embodiment, the at least one fixture hole may be arranged in one row or in a plurality of rows.

According to an example, non-limiting embodiment, the module may further include at least one second semiconductor device that may be mounted on the second surface of the printed circuit board.

According to an example, non-limiting embodiment, the module may further include a support at each of the at least one fixture holes that may protrude from the printed circuit board. A height of the fixture hole may be smaller than a height of the at least one connection terminal and greater than a height of the first and second semiconductor devices.

According to an example, non-limiting embodiment, the module may further include at least one stacking connection pad on the second surface of the printed circuit board.

### BRIEF DESCRIPTION OF THE DRAWINGS

Example, non-limiting embodiments will be described with reference to the attached drawings.

FIG. 1 is a cross-sectional view of a socketless planar semiconductor module according to an example, non-limiting embodiment.

FIG. 2 is a plan view of a socketless planar semiconductor module according to an example, non-limiting embodiment.

FIG. 3 is a bottom view of a socketless planar semiconductor module according to an example, non-limiting embodiment.

FIG. 4 is a plan view of a layout of connection terminals of a socketless planar semiconductor module according to an example, non-limiting embodiment.

FIG. 5 is a cross-sectional view of an example, non-limiting embodiment of a structure of the connection terminals in the example socketless planar semiconductor of FIG. 4;

FIG. 6 is a cross-sectional view of an example, non-limiting embodiment of a structure of the connection terminals in the example socketless planar semiconductor of FIG. 4;

FIG. 7 is a cross-sectional view of an example, non-limiting embodiment of a structure of the connection terminals in the example socketless planar semiconductor of FIG. 4;

FIG. 8 is a cross-sectional view of a socketless planar semiconductor module according to an example, non-limiting embodiment.

FIG. 9 is a cross-sectional view of a socketless planar semiconductor module according to an example, non-limiting embodiment.

FIG. 10 is a cross-sectional view of a socketless planar semiconductor module according to an example, non-limiting embodiment.

FIG. 11 is a cross-sectional view of a socketless planar semiconductor module according to an example, non-limiting embodiment.

FIG. 12 is a cross-sectional view of a stacked structure of the socketless planar semiconductor module according to another example, non-limiting embodiment.

### DESCRIPTION OF EXAMPLE NON-LIMITING EMBODIMENTS

Example, non-limiting embodiments will be described with reference to the accompanying drawings. The invention may, however, be embodied in many different forms and should not be construed as being limited to the embodiments set forth herein. Rather, the disclosed embodiments are provided so that this disclosure will be thorough and complete, and will fully convey the scope of the invention to those skilled in the art.

Well-known structures and processes are not described or illustrated in detail to avoid obscuring example embodiments.

An element is considered as being mounted (or provided) “on” another element when mounted (or provided) either directly on the referenced element or mounted (or provided) on other elements overlaying the referenced element. Throughout this disclosure, spatial terms such as “upper,” “lower,” “above” and “below” (for example) are used for convenience in describing various elements or portions or regions of the elements as shown in the figures. These terms do not, however, require that the structure be maintained in any particular orientation.

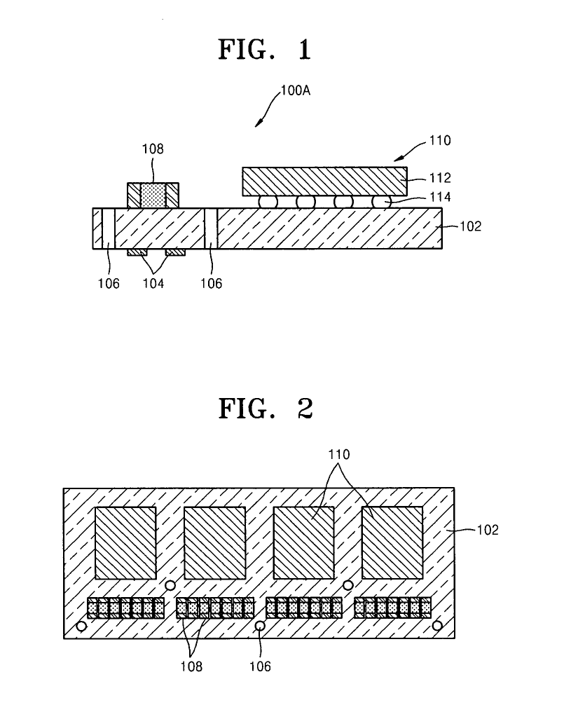

FIG. 1 is a cross-sectional view of a socketless planar semiconductor module according to an example, non-limiting embodiment.

Referring to FIG. 1, a socketless planar semiconductor module may include a printed circuit board 102 having a first surface, a second surface, and fixture holes 106. A semiconductor device 110 may be mounted on the first surface of the printed circuit board 102. Connection terminals 104 may be provided on either the first surface or the second surface of the printed circuit board 102 and may be connected with connection pads of a motherboard (not shown).

The socketless planar semiconductor module 100A may be connected with the motherboard using the fixture holes 106, such that one of the first surface or the second surface of the printed circuit board 102 may face the motherboard. The fixture holes 106 may be provided to assist in aligning the connection terminals 104 with the connection pads of the motherboard. In this way, the semiconductor module 100A may be aligned and connected with the motherboard using the fixture holes 106 and fixing members (not shown), for example, screws or rivets.

For example, the semiconductor module 100A may be a memory module. A passive device 108 may be mounted on a surface of the printed circuit board 102 that may serve to suppress electrical signal noise. Another semiconductor device may be mounted on a surface of the printed circuit board that may serve as a buffer.

For example, the semiconductor device 110 may be a ball grid array (BGA) package or a wafer level package (WLP), in which the external connection terminals 114 utilized to connect the semiconductor device 110 to the printed circuit board 102 may be conductive bumps. Alternatively, for example, the semiconductor device 110 may be a thin small out-line package (TSOP) or a thin quad flat package (TQFP), in which the external connection terminals 114 may be leads; or the semiconductor device 110 may be a semiconductor package or a stacked semiconductor package, in which the external connection terminals 114 may be lands and/or conductive bumps.

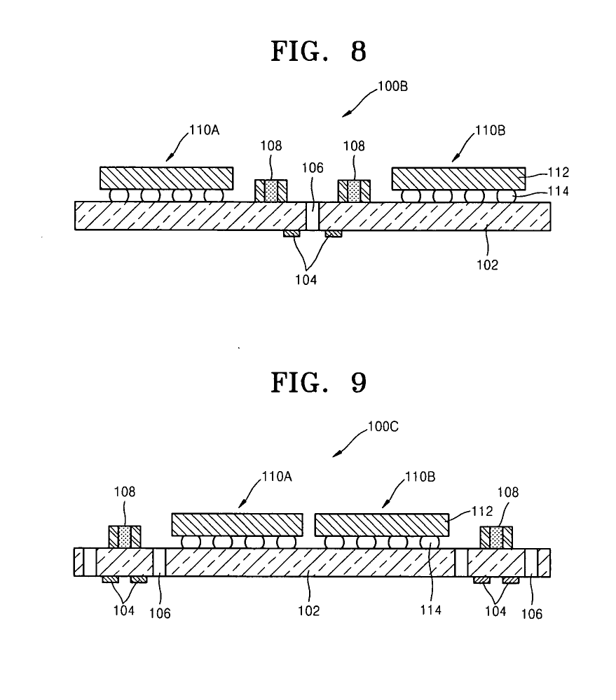

The semiconductor module 100A, for example, which may be a single in-line memory module (SIMM), which may have semiconductor devices 110 that may be mounted in one row on the printed circuit board 102, as shown in FIG. 1. However, the semiconductor module 100A, for example, may be a dual in-line memory module (DIMM), which may have semiconductor devices 110 that may be mounted in two rows, as in FIGS. 8 and 9. In FIG. 1, reference numeral 112 indicates a body of the semiconductor package.

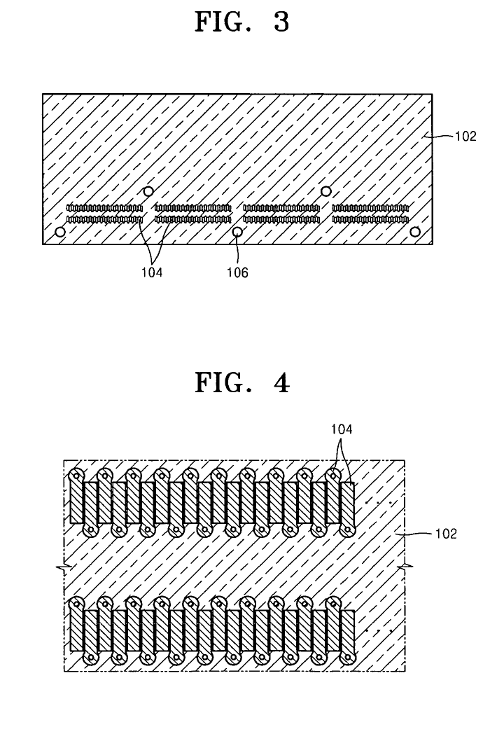

FIG. 2 is a plan view of the socketless planar semiconductor module according to an example, non-limiting embodiment. FIG. 3 is a bottom view of the socketless planar semiconductor module according to an example, non-limiting embodiment.

Referring to FIGS. 2 and 3, semiconductor devices 110 and passive devices 108 may be mounted on a first surface of a printed circuit board 102. Connection terminals 104 may be provided on a second surface of the printed circuit board 102. Fixture holes 106 may be provided in the printed circuit board 102 for connecting the semiconductor module with the mother board and for aligning the connection terminals 104 of the semiconductor module with the connection pads of the mother board.

For example, the connection terminals 104 may be arranged in two or more rows depending on the number of needed connection terminals 104.

For example, the fixture holes 106 may be arranged in two rows, for example staggered over and under the connection terminals 104. Alternatively, for example, the fixture holes 106 may be arranged in one row or in four corners of the semiconductor module. By way of example only, the fixture holes 106 may be circular, rectangular or triangular in shape.

The semiconductor module may be connected with or disconnected from the motherboard, for example, by inserting or extracting screws or rivets into or from the fixture holes 106. Thus, the socketless planar semiconductor module, for example, a memory module, may be changed or replaced freely.

FIG. 4 is a plan view of a layout of the connection terminals of the socketless planar semiconductor module according to an example, non-limiting embodiment.

Referring to FIG. 4, a socketless planar semiconductor module may include connection terminals 104 provided on a surface of a printed circuit board 102 that may be arranged in the same in layout as connection pads (not shown) formed in a motherboard. The number of connection pads of the motherboard may be equal to or smaller than that of a printed circuit pattern provided on the printed circuit board 102 for socket connection.

The connection terminals 104 may also be arranged in a staggered layout which may make it possible for more connection terminals 104 to be provided within a limited area. The connection terminals 104 may be arranged in a plurality of rows, for example, two rows, four rows, etc. The connection terminals 104 may have another arrangement that may stably connect between the semiconductor module and the connection pads of the motherboard and provide for ease of connection and disconnection.

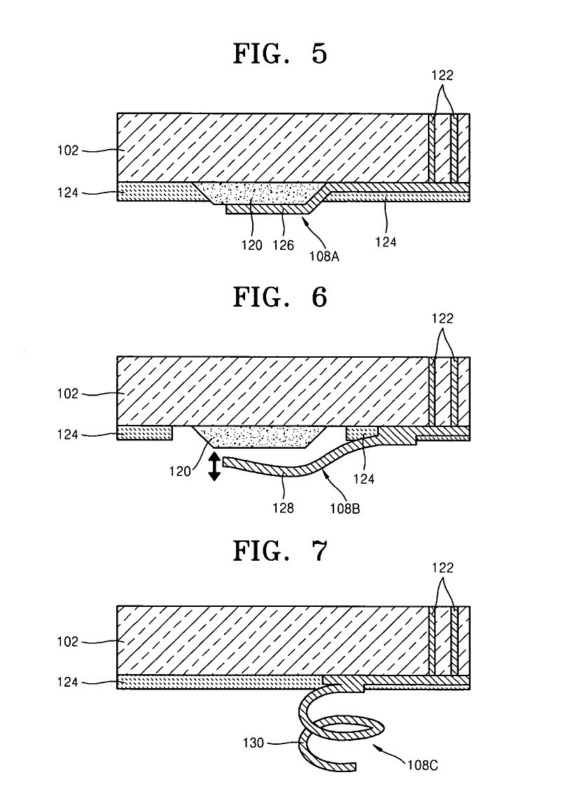

FIGS. 5 through 7 illustrate various example, non-limiting embodiments of the structure of the connection terminals in the socketless planar semiconductor of FIG. 4.

Referring to FIG. 5, a connection terminal 108A may be implemented using a fixed printed circuit pattern 126. An elastic member 120, for example, rubber, may be provided with a predetermined height on an insulating substrate of a printed circuit board 102. A fixed printed circuit pattern 126 may be provided on the elastic member 120 to form a connection terminal 108A. A resist 124 may be provided on the fixed printed circuit pattern 126 and the insulating substrate of the printed circuit board 102 for electrical insulation. The printed circuit board 102 may have through-holes 122 through which the fixed printed circuit pattern 126 may be electrically connected with a semiconductor device mounted on an opposite surface of the printed circuit board 102.

Referring to FIG. 6, a connection terminal 108B may be implemented using a metal pin 128. An elastic member 120 may be provided on an insulating substrate of a printed circuit board 102. A metal pin 128 may be provided on the elastic member 120 to be connected with a connection pad of a motherboard. For example, this structure may overcome a height difference that may occur between the motherboard and the semiconductor module by using free-play of the metal pin 128 (as indicated by an arrow). By way of example only, the metal pin 128 may be formed by bonding a metal pin to a metal pattern on the printed circuit board, for example, a metal pin used in a pin grid array (PGA) or a socket.

Referring to FIG. 7, a connection terminal 108C may be implemented using a metal spring 130. An elastic member 120 may be provided on an insulating substrate of a printed circuit board 102. A metal spring 130 may be provided on the elastic member 120 to be connected with a connection pad of a motherboard. For example, this structure of the connection terminal 108C may compensate for a height difference that may occur between the motherboard and the semiconductor module.

FIG. 8 is a cross-sectional view of a socketless planar semiconductor module according to an example, non-limiting embodiment. FIG. 9 is a cross-sectional view of a socketless planar semiconductor module according to another example, non-limiting embodiment.

Referring to FIGS. 8 and 9, planar semiconductor modules 100B and 100C may include a first semiconductor device 110A and a second semiconductor device 110B that may both be mounted on the first surface of the printed circuit board 102. Referring to FIG. 8, semiconductor devices 110A and 110B may be arranged in two rows to increase the capacity of a semiconductor memory on a printed circuit board 102. Referring to FIG. 9, the planar semiconductor module 100C may have connection terminals 104 arranged in four rows. For example, the operation speed of the semiconductor module 100C may be increased by laying out the semiconductor devices 110A and 110B in four rows and by laying out the connection terminals 104 on both ends of the printed circuit board 102.

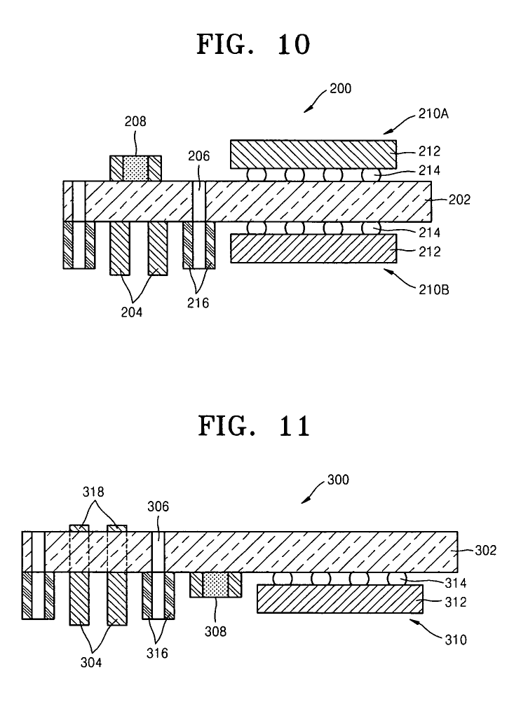

FIG. 10 is a cross-sectional view of a socketless planar semiconductor module according to another example, non-limiting embodiment.

Referring to FIG. 10, a socketless planar semiconductor module 200 may include a printed circuit board 202 having a first surface and a second surface. A first semiconductor device 210A may be mounted on a first surface of the printed circuit board 202 and a second semiconductor device 210B may be mounted on the second surface of the printed circuit board 202. Connection terminals 204 may be provided on one of the first surface or the second surface of the printed circuit board 202 and may be connected with connection pads of a motherboard (not shown). Fixture holes 206 may be provided in the printed circuit board 202 for aligning the connection terminals 204 with the connection pads of the motherboard such the that one of the first surface or the second surface of the printed circuit board may be facing the motherboard.

A support 216 may provided for each fixture hole 206 and may protrude from a surface of the printed circuit board 202. A height of the support 216 may be smaller than a height of the connection terminal 204 and greater than a height of the semiconductor devices 210A and 210B. By way of example only, the support 216 may be composed of an insulating material that may be durable enough to stably support the semiconductor module 200 on the motherboard.

For example, the support 216 may compensate for a height difference between the semiconductor device 21 0B and the connection terminal 204, prevent the semiconductor module 200 from being slanted, and/or prevent a center of gravity of the semiconductor module 200 from being concentrated on the connection terminal 204. It will be appreciated that the layout of the connection terminals 204, the shape of the fixture holes 206, and the shape of the supports 216 may be varied.

FIG. 11 is a cross-sectional view of a socketless planar semiconductor module according to another example, non-limiting embodiment.

Referring to FIG. 11, a socketless planar semiconductor module 300 may include a printed circuit board 302 having a first surface and a second surface. A semiconductor device 310 may be mounted on the first surface of the printed circuit board 302. Connection terminals 304 may be provided one of the first surface or the second surface of the printed circuit board 302 and connected with connection pads of a motherboard (not shown). Stacking connection pads 318 may be provided on the second surface of the printed circuit board 302. Fixture holes 306 may be provided in the printed circuit board 302 for aligning the connection terminals 304 with the connection pads of the motherboard such that one of the first surface or the second surface of the printed circuit board may be facing the motherboard.

A support 316 may be provided for each fixture hole 306 and may protrude from the printed circuit board 302. By way of example only, the support 316 may be composed of an insulating material that may be durable enough to stably support the semiconductor module 300 on the motherboard. A height of the support 316 may be smaller than the height of the connection terminal 304 and greater than the height of the semiconductor devices 310.

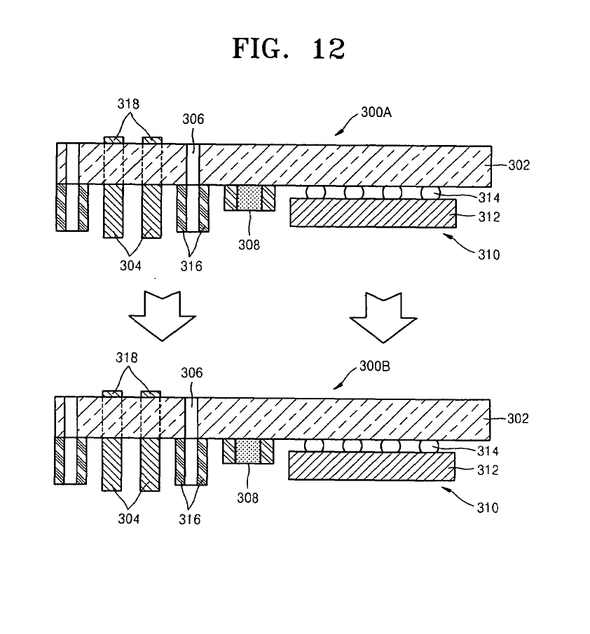

FIG. 12 is a cross-sectional view of a stacked structure of two planar semiconductor modules according to an example, non-limiting embodiment.

Referring to FIG. 12, two stackable planar semiconductor modules 300A and 300B may be stacked on each other. Connection terminals 304 of the first semiconductor module 300A may be electrically connected with stacking connection pads 318 provided on the printed circuit board of the second semiconductor module 300B, thereby completing the stacking of the two planar semiconductor modules 300A and 300B. It will be appreciated that three or more planar semiconductor modules may be stacked on each other. Further, a combination in which a semiconductor module according to the example, non-limiting embodiment of FIG. 10 may be stacked on a semiconductor module according to the example, non-limiting embodiment of FIG. 11 may provide a stacked semiconductor module having double capacity.

In accordance with example, non-limiting embodiments, a socketless planar semiconductor module may allow the height for the semiconductor module connection to be reduced by connecting the semiconductor module with the motherboard in a horizontal direction rather than in a vertical direction. Thus, it may be possible to more efficiently mount the semiconductor module in a slim digital device.

Further, the electrical signal characteristic may be enhanced and the frequency of connection defect generation may be reduced because the socketless planar semiconductor module does not require the use of an interconnect, for example a concave-shaped socket.

In addition, socketless planar semiconductor modules may be efficiently stacked within a limited area.

Although example, non-limiting embodiments have been described in detail herein, it should be understood those of ordinary skill in the art that various changes may be suitably implemented without departing from the spirit and scope of the present invention as defined by the appended claims and their equivalents.

What is claimed is:

1. A socketless planar semiconductor module comprising:
a printed circuit board having a first surface, a second surface and at least one fixture hole;
at least one first semiconductor device mounted on the first surface of the printed circuit board; and
at least one connection terminal provided on one of the first surface and the second surface of the printed circuit board to connect to a motherboard at a connection pad,
wherein the printed circuit board connects to the motherboard through the at least one fixture hole such the connection terminals align with the connection pad and one of the first surface and second surface of the printed circuit board face a major surface of the motherboard.

2. The module of claim 1, wherein the at least one first semiconductor device is mounted on the printed circuit board using leads.

3. The module of claim 1, wherein the at least one first semiconductor device is mounted on the printed circuit board using conductive bumps.

4. The module of claim 1, wherein the at least one first semiconductor device is a plurality of semiconductor devices, the plurality of semiconductor devices mounted on the first surface of the printed circuit board and arranged in one row.

5. The module of claim 1, wherein the at least one first semiconductor device is a plurality of semiconductor devices, the plurality of semiconductor devices mounted on the first surface of the printed circuit board and arranged in two rows.

6. The module of claim 1, wherein the at least one connection terminal is a printed circuit pattern on an elastic member on the printed circuit board.

7. The module of claim 1, wherein the at least one connection terminal is a metal pin on an elastic member on the printed circuit board.

8. The module of claim 1, wherein the at least one connection terminal is a metal spring on the printed circuit board.

9. The module of claim 1, wherein the at least one connection terminal is a plurality of connection terminals arranged in a staggered layout.

10. The module of claim 1, wherein the at least one connection terminal is a plurality of connection terminals arranged in a plurality of rows.

11. The module of claim 1, wherein the at least one fixture hole is a plurality of fixture holes arranged in one row.

12. The module of claim 1, wherein the at least one fixture hole is a plurality of fixture holes arranged in a plurality of rows.

13. The module of claim 12, wherein the socketless planar semiconductor module is a memory module.

14. The module of claim 1, further comprising at least one second semiconductor device mounted on the second surface of the printed circuit board.

15. The module of claim 14, further comprising a support at each of the at least one fixtures hole that protrudes from the printed circuit board.

16. The module of claim 15, wherein a height of each support is smaller than a height of the at least one connection terminal and greater than a height of the first and second semiconductor devices.

17. The module of claim 1, further comprising at least one stacking connection pad on the second surface of the printed circuit board.

18. The module of claim 17, further comprising a support at each fixture hole that protrudes from the printed circuit board.

19. The module of claim 18, wherein a height of each support is smaller than a height of the at least one connection terminal and greater than a height of the first and second semiconductor devices.
